(19) United States
(12) Patent Application Publication
(10) Pub. No.: US 2016/0033836 A1
(43) Pub. Date: Feb. 4, 2016

(54) BLACK MATRIX AND FABRICATION METHOD THEREOF, DISPLAY PANEL AND DISPLAY DEVICE

(71) Applicant: BOE Technology Group Co.,Ltd., Beijing (CN)

(72) Inventor: Juan CHEN, Beijing (CN)

(73) Assignee: BOE Technology Group Co., Ltd., Beijing (CN)

(21) Appl. No.: 14/421,681

(22) PCT Filed: Aug. 1, 2014
(86) PCT No.: PCT/CN2014/083566

§ 371 Date: Feb. 13, 2015

(30) Foreign Application Priority Data
Jan. 8, 2014 (CN) 201410008527.9

(51) Int. Cl. G02F 1/15; G02F 1/155; G03F 7/00; G02F 1/161

(52) U.S. Cl. CPC G02F 1/15; G02F 1/161; G02F 1/155; G03F 7/0007; G02F 2001/1515; G02F 2001/1519

(57) ABSTRACT

Embodiments of the disclosure disclose a black matrix and a fabrication method thereof, a display panel and a display device. The black matrix comprises: a first transparent electrode layer and a second transparent electrode layer stacked on a substrate, and an electrochromic layer provided between the first transparent electrode layer and the second transparent electrode layer. The electrochromic layer is black when there is a voltage difference between the first transparent electrode layer and the second transparent electrode layer, and the electrochromic layer is transparent when there is no voltage difference between the first transparent electrode layer and the second transparent electrode layer.

### TECHNICAL FIELD

Embodiments of the disclosure relate to a black matrix and a fabrication method thereof, a display panel and a display device.

### BACKGROUND

A black matrix is an important part of a display panel, and a non-display region of the display panel is blocked by the black matrix so that a display region for displaying an image is exposed. FIG. 1 shows a black matrix 2 disposed on a color filter substrate in the prior art. As shown in FIG. 1, the black matrix 2 is formed on a base substrate 1 of the color filter substrate in a grid-like manner, and typically the black matrix 2 is made of an acrylic resin doped with conductive black carbon particles.

For TVs and mobile products, in a process of curing a sealant, as shown in FIG. 2, ultraviolet light is needed to irradiate from a side where the black matrix 2 is formed onto the sealant 3; and in this case, the black matrix 2 blocks the ultraviolet light so that a portion of the energy of the ultraviolet light cannot reach the sealant 3, and as a result, the sealant 3 cannot be cured sufficiently and the sealing effect is degraded.

### SUMMARY

According to the embodiments of the present disclosure, a black matrix is provided. The black matrix comprises: a first transparent electrode layer and a second transparent electrode layer stacked on a substrate, and an electrochromic layer provided between the first transparent electrode layer and the second transparent electrode layer. The electrochromic layer is black when there is a voltage difference between the first transparent electrode layer and the second transparent electrode layer, and the electrochromic layer is transparent when there is no voltage difference between the first transparent electrode layer and the second transparent electrode layer.

For example, the second transparent electrode layer is far away from the substrate, both the second transparent electrode layer and the electrochromic layer are of a grid-like structure, and openings of the electrochromic layer and openings of the second transparent electrode layer are disposed to correspond to each other one by one.

For example, the electrochromic layer comprises an electrolyte film and an electrochromic film disposed in a stacking manner.

For example, the electrolyte film is made of a polymer electrolyte.

For example, the polymer electrolyte is carbonate acrylate and lithium perchlorate.

For example, the electrochromic film is made of an organic conductive polymer material.

For example, the organic conductive polymer material is polyaniline or polythiophene.

For example, the first transparent electrode layer, the electrochromic layer and the second transparent electrode layer are all of a grid-like structure, and openings of the first transparent electrode layer, openings of the electrochromic layer, and openings of the second transparent electrode layer are disposed to correspond to one another one by one.

According to the embodiments of the present disclosure, a fabrication method of a black matrix is provided. The method comprises: forming a first transparent electrode layer on a substrate; forming an electrochromic layer on the first transparent electrode layer; forming a second transparent electrode layer on the electrochromic layer. The electrochromic layer is black when there is a voltage difference between the first transparent electrode layer and the second transparent electrode layer, and the electrochromic layer is transparent when there is no voltage difference between the first transparent electrode layer and the second transparent electrode layer.

For example, the forming the electrochromic layer on the first transparent electrode layer comprises: forming an electrolyte film on the first transparent electrode layer and forming an electrochromic film on the electrolyte film; or forming the electrochromic film on the first transparent electrode layer and forming the electrolyte film on the electrochromic film.

For example, the method further comprises: performing a patterning process on the second transparent electrode layer and the electrochromic layer to form the second transparent electrode layer and the electrochromic layer which have a grid-like structure, wherein openings of the electrochromic layer and openings of the second transparent electrode layer are disposed to correspond to each other one by one.

For example, the method further comprises: performing a patterning process on the second transparent electrode layer, the electrochromic layer and the first transparent electrode layer to form the first transparent electrode layer, the electrochromic layer and the second transparent electrode layer which have a grid-like structure, wherein openings of the first transparent electrode layer, openings of the electrochromic layer, and openings of the second transparent electrode layer are disposed to correspond one another one by one.

According to the embodiments of the present disclosure, a display panel is provided. The display panel comprises an array substrate and a color filter substrate. The array substrate or the color filter substrate comprises the black matrix as described above.

According to the embodiments of the present disclosure, a display device is provided. The display device comprises the display panel as described above.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a structural schematic view illustrating a black matrix in the prior art;

FIG. 2 is a schematic view illustrating a display panel of the prior art upon curing a sealant;

FIG. 3 is a structural schematic view illustrating a black matrix according to an embodiment of the present disclosure;

FIG. 4 is another structural schematic view illustrating the black matrix according to the embodiment of the present disclosure;

FIG. 5 is a schematic view illustrating a display panel according to an embodiment of the present disclosure upon sealing the display panel;

FIG. 6 is a schematic view illustrating the black matrix according to the embodiment of the present disclosure upon sealing the display panel;

FIG. 7 is a schematic view illustrating the black matrix according to the embodiment of the present disclosure when the display panel is working;

FIG. 8 is a schematic view illustrating the display panel according to the embodiment of the present disclosure when it is not working; and

FIG. 9 is a schematic view illustrating the display panel according to the embodiment of the present disclosure when it is working.

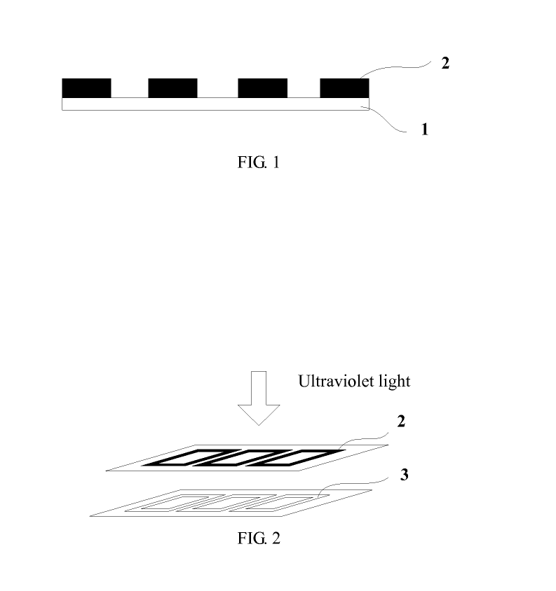

### DESCRIPTION OF THE EMBODIMENTS

In order to make objects, technical details and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

In order to improve a sealing effect of a display panel, the embodiments of the present disclosure provide a black matrix and a fabrication method thereof, a display panel and a display device. In an embodiment of the present disclosure, the black matrix is of an electrochromic structure, and the black matrix is in a transparent state when it is powered off. When the display panel is sealed, ultraviolet light irradiates directly onto a sealant via the black matrix in the transparent state, and thus the sealing effect of the display panel can be improved.

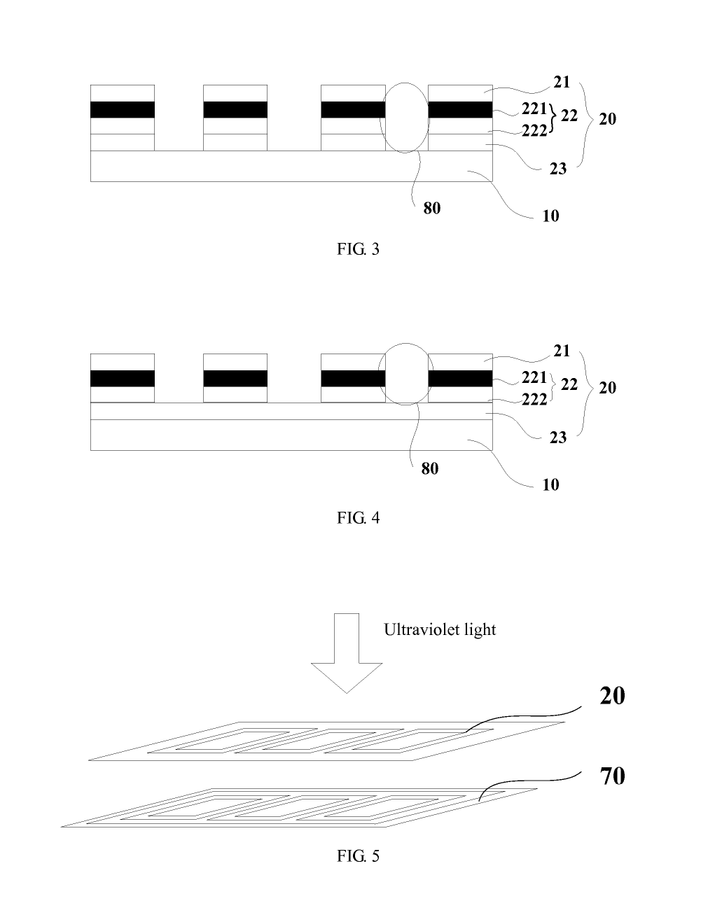

As shown in FIG. 3 and FIG. 4, the black matrix 20 according to the embodiment of the present disclosure comprises two transparent electrode layers stacked on a substrate 10, and an electrochromic layer 22 provided between the two transparent electrode layers. When there is a voltage difference between the two transparent electrode layers (i.e., when the black matrix 20 is powered on), the electrochromic layer 22 is black, and when there is not a voltage difference between the two transparent electrode layers (i.e., when the black matrix 20 is powered off), the electrochromic layer 22 is transparent.

In the black matrix 20 according to the embodiment of the present disclosure, both the transparent electrode layer far away from the substrate 10 and the electrochromic layer are of a grid-like structure, and openings of the electrochromic layer 22 and openings of the transparent electrode layer far away from the substrate are disposed to correspond to each other one by one. When the display panel is fabricated, one opening corresponds to a region of one sub-pixel.

It should be noted that, although it is shown in the drawings that the openings are rectangles, yet the embodiments of the present disclosure are not limited thereto. In practice, the black matrix 20 needs to block a TFT in addition to gate lines and data lines and a shape of the sub-pixel is variable, so the openings of the black matrix 20 are of different shapes which can be selected according to practical requirements.

For example, the black matrix 20 may be disposed on a color filter substrate, or may be disposed on an array substrate.

For example, as shown in FIG. 5, the black matrix 20 is formed on the color filter substrate, and the sealant is coated in a peripheral region of the array substrate so as to bond the color filter substrate with the array substrate. The ultraviolet light is incident vertically from a side of the color filter substrate so that the sealant is cured. The black matrix 20 is controlled to be in the transparent state, the ultraviolet light directly irradiates onto the sealant 70 through the black matrix 20 provided on the edge of the color filter substrate, and the sealant 70 is sufficiently cured under sufficient radiation of the ultraviolet light. Thus, the sealing effect of the display panel is improved. It should be noted that, FIG. 5 only shows the black matrix 20 provided in the peripheral region of the display panel.

The black matrix 20 comprises two transparent electrode layers disposed in a stacking manner. The transparent electrode layer close to the substrate 10 is a first transparent electrode layer 23, and the transparent electrode layer far away from the substrate 10 is a second transparent electrode layer 21. The black matrix 20 further comprises the electrochromic layer 22 disposed between the first transparent electrode layer 23 and the second transparent electrode layer 21. With reference to FIG. 3 and FIG. 4, the electrochromic layer 22 comprises an electrolyte film 222 and an electrochromic film 221 disposed in a stacking manner. It should be noted that, the stacking sequence of the electrochromic film 221 and the electrolyte film 222 is not limited. For example, as shown in FIG. 3 and FIG. 4, the electrolyte film 222 is formed on the first transparent electrode layer 23 and the electrochromic film 221 is formed on the electrolyte film 222. For example, the electrochromic film 221 is formed on the first transparent electrode layer 23 and the electrolyte film 222 is formed on the electrochromic film 221.

Next, an operation principle of the black matrix according to the embodiment of the present disclosure will be described in detail.

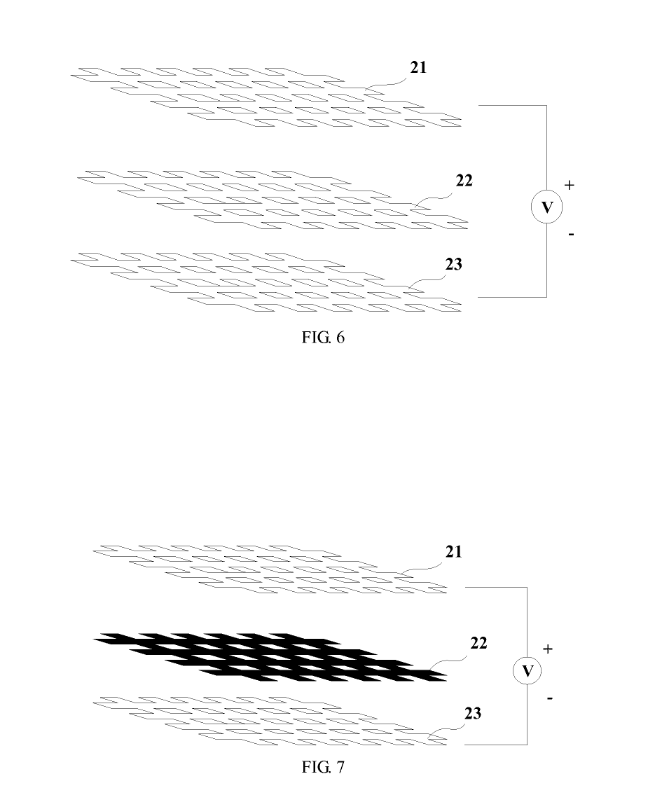

As shown in FIG. 6, when there is not the voltage difference between the first transparent electrode layer 23 and the second transparent electrode layer 21, the electrochromic layer 22 is in the transparent state. As shown in FIG. 7, when there is the voltage difference between the first transparent electrode layer 23 and the second transparent electrode layer 21, the first transparent electrode layer 23, the electrolyte film 222, the electrochromic film 221 and the second transparent electrode layer 21 form a loop, ions in the electrolyte film 222 are released into the electrochromic film 221, so that the electrochromic film 221 becomes black and the black matrix 20 is capable of blocking the non-display region of the display panel. When the display panel is in a working state, the voltage difference is applied between the first transparent electrode layer 23 and the second transparent electrode layer 21, so that the black matrix 20 on the display panel is in the black state and the display panel normally works. When the display panel is sealing as shown in FIG. 5, the voltage difference is not applied between the first transparent electrode layer 23 and the second transparent electrode layer 21, the electrochromic layer 22 in the black matrix 20 is in the transparent state as shown in FIG. 6, the ultraviolet light directly irradiates onto the sealant 70 through the transparent electrochromic layer 22, so that the sealant 70 is sufficiently cured and the sealing effect of the sealant 70 is improved.

For example, the electrolyte film 222 is made of polymer electrolyte, the polymer electrolyte is poly(2-acrylamido-2-methyl-1-propanesulfonic acid), polyethylene oxide, lithium perchlorate, carbonate acrylate electrolyte, etc., and contains a large amount of ions. These ions are capable of being quickly released after power is on. For example, the polymer electrolyte used in the embodiment of the present disclosure is carbonate acrylate and lithium perchlorate in order to achieve a good conductive effect.

For example, the electrochromic film 221 is made of an organic conductive polymer material, and the organic conductive polymer material is polythiophenes and derivatives thereof, viologen compounds, etc., e.g., magnesium fluoride, lithium tetrafluoride, polyaniline, polythiophene, etc. For example, the organic conductive polymer material used in the embodiment of the present disclosure is polyaniline or polythiophene. The organic conductive polymer material is transparent when power is off. After power is on, the ions in the gelatinous electrolyte film 222 made of the carbonate acrylate electrolyte and lithium perchlorate electrolyte are released into the electrochromic film 221 made of polyaniline or polythiophene, so that the electrochromic film 221 becomes black and the display panel works normally.

When the black matrix 20 is formed on the color filter substrate, a color filter may be disposed within the openings of the black matrix 20.

FIG. 3 and FIG. 4 show different structures of the black matrix 20. As shown in FIG. 3, the first transparent electrode layer 23, the second transparent electrode layer 21 and the electrochromic layer 22 in the black matrix 20 are all of the grid-like structure, the openings of the first transparent electrode layer 23, the openings of the second transparent electrode layer 21 and the openings of the electrochromic layer 22 are disposed to correspond to one another one by one; and when the black matrix 20 is formed on the color filter substrate, the openings of the first transparent electrode layer 23, the openings of the second transparent electrode layer 21 and the openings of the electrochromic layer 22 together form a space 80 for accommodating the color filter. As shown in FIG. 4, the first transparent electrode layer 23 in the black matrix 20 is of a planar structure without openings, both the second transparent electrode layer 21 and the electrochromic layer 22 are of the grid-like structure, the openings of the second transparent electrode layer 21 and the openings of the electrochromic layer 22 are disposed to correspond to each other; and when the black matrix 20 is formed on the color filter substrate, the openings of the second transparent electrode layer 21 and the openings of the electrochromic layer 22 together form the space 80 for accommodating the color filter. It should be noted that, the structure of the black matrix according to the embodiment of the present disclosure is not limited to the structure as described above.

An embodiment of the present disclosure provides a fabrication method of a black matrix, the method comprising steps of: forming a first transparent electrode layer on a substrate; forming an electrochromic layer on the first transparent electrode layer; and forming a second transparent electrode layer on the electrochromic layer.

For example, the step of forming the electrochromic layer on the first transparent electrode layer comprises: forming an electrolyte film on the first transparent electrode layer and forming an electrochromic film on the electrolyte film; or forming the electrochromic film on the first transparent electrode layer and forming the electrolyte film on the electrochromic film.

Further, the method comprises: performing a patterning process at least on the second transparent electrode layer and the electrochromic layer to form the black matrix having a grid-like structure. For example, the patterning process comprises steps of coating a photoresist, exposing and developing the photoresist, etching, stripping the photoresist, etc.

The step of performing the patterning process at least on the second transparent electrode layer and the electrochromic layer to form the black matrix having a grid-like structure for example comprises: performing the patterning process on the second transparent electrode layer and the electrochromic layer to form the black matrix as shown in FIG. 4; or performing the patterning process on the second transparent electrode layer, the electrochromic layer and the first transparent electrode layer to form the black matrix as shown in FIG. 3.

By using the above-described method, the black matrix having the electrochromic structure is formed, so that the sealing effect of the display panel can be improved while normal operation of the display panel can be ensured.

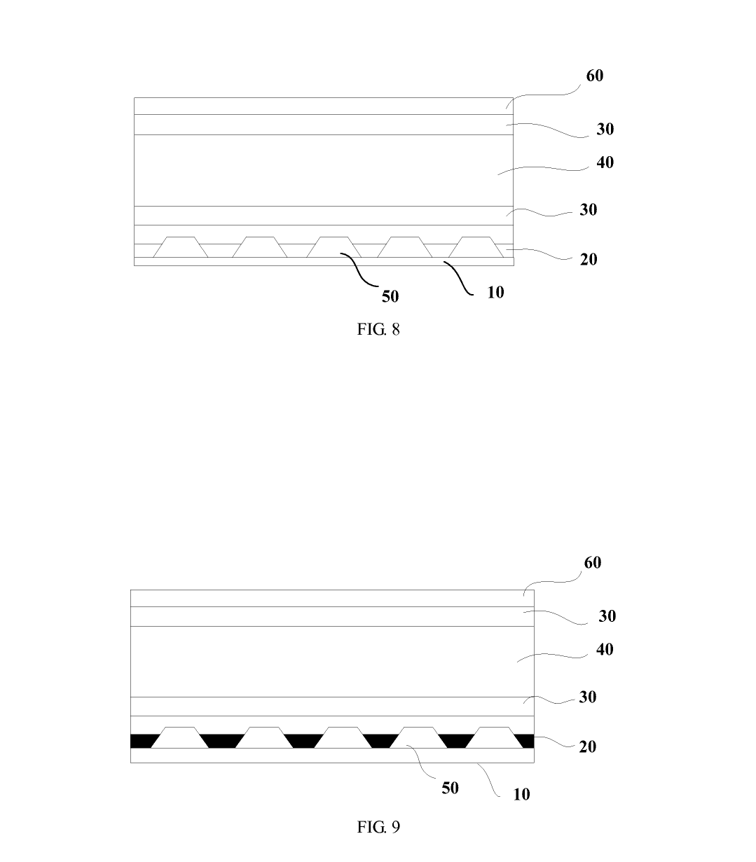

An embodiment of the present disclosure provides a display panel, the display panel comprising an array substrate and a color filter substrate. The color filter substrate or the array substrate comprises the above-described black matrix, i.e., the black matrix may be disposed on the color filter substrate, or may be disposed on the array substrate. Hereinafter, the display panel according to the embodiment of the present disclosure will be described with a case that the black matrix is disposed on the color filter substrate as an example. FIG. 8 is a schematic view illustrating the display panel according to the embodiment of the present disclosure when it is not working; and FIG. 9 is a schematic view illustrating the display panel according to the embodiment of the present disclosure when it is working. With reference to FIG. 8 and FIG. 9, the display panel according to the embodiment of the present disclosure comprises: a color filter substrate 10, an array substrate 60 bonded with the color filter substrate 10, two alignment layers 30 respectively disposed on inner sides of the color filter substrate and the array substrate 60, and a liquid crystal layer 40 disposed between the two alignment layers 30. The black matrix 20 is disposed on the color filter substrate 10, and a color filter layer 50 is disposed within the openings of the black matrix 20.

As shown in FIG. 8, when the display panel is sealed, there is no voltage difference between the first transparent electrode layer 23 and the second transparent electrode layer 21, the black matrix 20 is in the transparent state, and the ultraviolet light directly irradiates onto the sealant 70 through the black matrix 20 which is in the transparent state and is provided on the edge of the display panel. Thus, the sealing effect of the sealant 70 is improved, and further the quality of the entire display panel is improved. As shown in FIG. 9, when the display panel is working, there is the voltage difference between the first transparent electrode layer 23 and the second transparent electrode layer 21, and the black matrix 20 becomes black to effectively block the non-display region of the display panel.

An embodiment of the present disclosure provides a display device, and the display device comprises any one of the above-described display panels.

The foregoing embodiments merely are exemplary embodiments of the disclosure, and are not intended to define the scope of the disclosure, and the scope of the disclosure is determined by the appended claims.

The present application claims priority of Chinese Patent Application No. 201410008527.9 filed on Jan. 8, 2014, the disclosure of which is incorporated herein by reference in its entirety as part of the present application.

1. A black matrix, comprising: a first transparent electrode layer and a second transparent electrode layer stacked on a substrate, and an electrochromic layer provided between the first transparent electrode layer and the second transparent electrode layer,
wherein the electrochromic layer is black when there is a voltage difference between the first transparent electrode layer and the second transparent electrode layer, and the electrochromic layer is transparent when there is no voltage difference between the first transparent electrode layer and the second transparent electrode layer.

2. The black matrix according to claim 1, wherein
the second transparent electrode layer is far away from the substrate,
both the second transparent electrode layer and the electrochromic layer are of a grid-like structure, and openings of the electrochromic layer and openings of the second transparent electrode layer are disposed to correspond to each other one by one.

3. The black matrix according to claim 1, wherein
the electrochromic layer comprises an electrolyte film and an electrochromic film disposed in a stacking manner.

4. The black matrix according to claim 3, wherein the electrolyte film is made of a polymer electrolyte.

5. The black matrix according to claim 4, wherein the polymer electrolyte is carbonate acrylate and lithium perchlorate.

6. The black matrix according to claim 3, wherein the electrochromic film is made of an organic conductive polymer material.

7. The black matrix according to claim 6, wherein the organic conductive polymer material is polyaniline or polythiophene.

8. The black matrix according to claim 1, wherein
the first transparent electrode layer, the electrochromic layer and the second transparent electrode layer are all of a grid-like structure, and openings of the first transparent electrode layer, openings of the electrochromic layer, and openings of the second transparent electrode layer are disposed to correspond to one another one by one.

9. A fabrication method of a black matrix, comprising:
forming a first transparent electrode layer on a substrate;
forming an electrochromic layer on the first transparent electrode layer;
forming a second transparent electrode layer on the electrochromic layer;
wherein the electrochromic layer is black when there is a voltage difference between the first transparent electrode layer and the second transparent electrode layer, and the electrochromic layer is transparent when there is no voltage difference between the first transparent electrode layer and the second transparent electrode layer.

10. The fabrication method of the black matrix according to claim 9, wherein the forming the electrochromic layer on the first transparent electrode layer comprises:
forming an electrolyte film on the first transparent electrode layer and forming an electrochromic film on the electrolyte film; or
forming the electrochromic film on the first transparent electrode layer and forming the electrolyte film on the electrochromic film.

11. The fabrication method of the black matrix according to claim 10, further comprising:
performing a patterning process on the second transparent electrode layer and the electrochromic layer to form the second transparent electrode layer and the electrochromic layer which have a grid-like structure, wherein openings of the electrochromic layer and openings of the second transparent electrode layer are disposed to correspond to each other one by one.

12. The fabrication method of the black matrix according to claim 10, further comprising:
performing a patterning process on the second transparent electrode layer, the electrochromic layer and the first transparent electrode layer to form the first transparent electrode layer, the electrochromic layer and the second transparent electrode layer which have a grid-like structure, wherein openings of the first transparent electrode layer, openings of the electrochromic layer, and openings of the second transparent electrode layer are disposed to correspond one another one by one.

13. A display panel, comprising an array substrate and a color filter substrate, wherein the array substrate or the color filter substrate comprises the black matrix according to claim 1.

14. (canceled)
